(19) United States
(12) Patent Application Publication
(10) Pub. No.: US 2014/0193193 A1
(43) Pub. Date: Jul. 10, 2014

(54) TIME-DELAYED LATCH

(71) Applicants: Jered H. WIKANDER, Portland, OR (US); George H. DASKALAKIS, Forest Grove, OR (US); Denica N. LARSEN, Hillsboro, OR (US)

(72) Inventors: Jered H. WIKANDER, Portland, OR (US); George H. DASKALAKIS, Forest Grove, OR (US); Denica N. LARSEN, Hillsboro, OR (US)

(21) Appl. No.: 14/142,665

(22) Filed: Dec. 27, 2013

Related U.S. Application Data
(60) Provisional application No. 61/750,304, filed on Jan. 8, 2013.

(51) Int. Cl. H05K 5/02

(52) U.S. Cl. CPC H05K 5/0221
USPC 403/322.1

(57) ABSTRACT

A device, system, and method are described. In one embodiment, the device includes a latch. The latch at different times is located in at least a rest position and a non-rest position. The latch receiving a manipulation force to move the latch from the rest position to the non-rest position. The latch is capable of delaying its return to the rest position after a period of time.

### RELATED FIELD

The subject relates to a latch capable of attaching two portions of a computing device together.

### BACKGROUND

Detachable convertible notebook/tablet systems have the challenge of needing a latch for docking and undocking the tablet portion to the base. There are currently latching mechanisms on the market that are housed inside a cradle that provide a retention method.

Two hands are needed at the same time to unlatch these mechanisms which can be cumbersome, especially in an instance where only one hand is free. With these current mechanisms one hand holds the latch in the open position while the other hand pulls the tablet from the base.

### BRIEF DESCRIPTION OF THE DRAWINGS

FIG. 1 illustrates an embodiment of a detachable convertible device in an attached state.

FIG. 2 illustrates an embodiment of the detachable convertible device in a detached state.

FIG. 3 illustrates an embodiment of the detachable convertible device in a detached state from an alternate viewing angle.

FIG. 4 illustrates an embodiment of a mechanical stop latch mechanism in an unattached state.

FIG. 5 illustrates another embodiment of a mechanical stop that keeps the latch open when actuated and that resets once the user pulls the tablet away from the base.

FIG. 6 illustrates an embodiment of an electrical latch actuator to provide a time delay, which again will allow the user enough time to retrieve the detachable tablet.

FIG. 7 illustrates system hardware logic that may be present in the detachable convertible device.

### DETAILED DESCRIPTION

Embodiments of a detachable convertible latch mechanism for single-handed detachment are described. Generally, these embodiments allow a user to first unlock (i.e., unlatch) a tablet portion from the base portion of the detachable convertible device. Then, after the unlatching, either hand can reach up and pull the tablet portion off. This sequential operation requires that the latch be held open for long enough so that the user has time to retrieve the tablet. Embodiments that keep the latch open for a period of time are described.

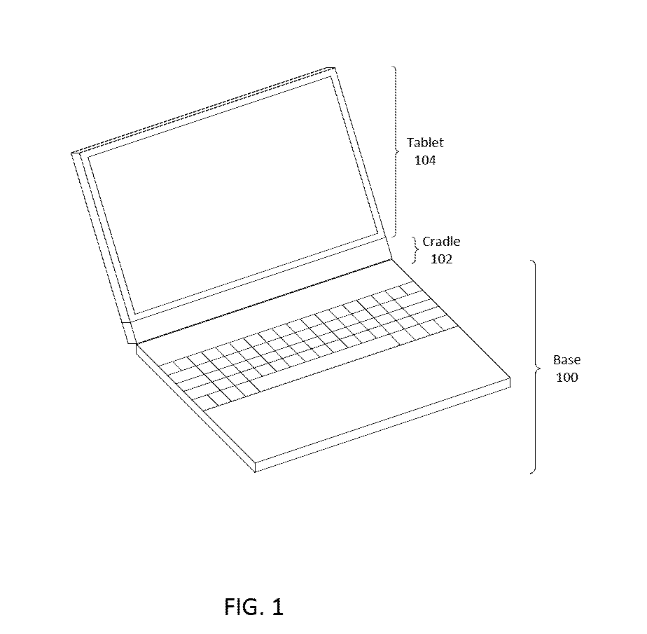

FIG. 1 illustrates an embodiment of a detachable convertible device in an attached state. In this form, the device may be considered a laptop, notebook, 2-in-1, or another type of detachable convertible in an attached state. The detachable convertible device may have a base portion 100, a cradle portion 102, and a tablet portion 104. The detachable convertible device shown has the tablet portion 104 attached and affixed to the cradle portion 102. The cradle portion 102 is permanently attached to the base portion 100 by a hinge that rotates the cradle portion 102 in relationship to the base portion 100 along the axis of the hinge. Each portion has a casing, which can be described as the outside shell of the portion of the device. The casing of the base portion 100 generally may house a keyboard and potentially one or more mouse pointer devices. The casing of the tablet portion 104 generally may house a display screen. In many embodiments, the display may be touch-sensitive using pressure touch, capacitive touch, or any other touch technology available. The casing of the cradle portion 102 generally may house a latch mechanism, which may be referred to as a hook latch assembly. In other embodiments that are not shown, the cradle portion 102 may be reduced in size so that it does not extend the length of the edge of the base or tablet portions, but rather is simply includes a housing just around the latch mechanism itself. Additionally, in other embodiments that are not shown, the cradle portion 102 may rotate around a center portion of the hinge to allow the cradle and tablet portions to face the opposite direction from the direction shown in FIG. 1.

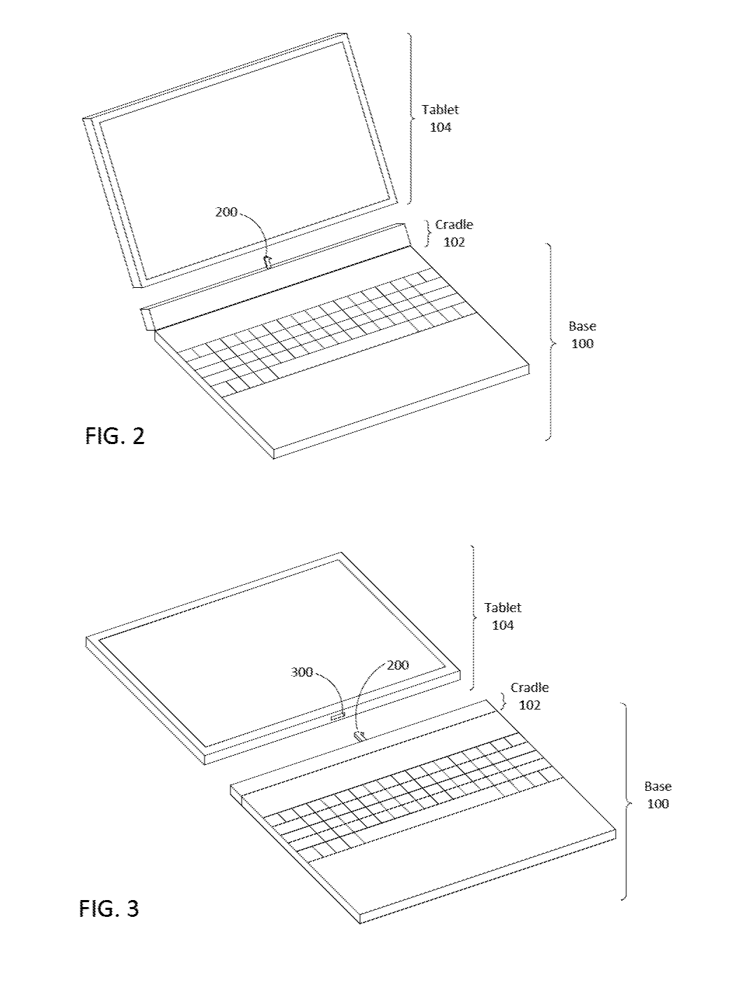

FIG. 2 illustrates an embodiment of the detachable convertible device in a detached state. In this state, the device from FIG. 1 now is shown with the tablet portion 104 detached from the cradle portion 102. In many embodiments, the hook portion 200 (also referred to as a hook tab, latch tab, or hook latch tab) of the latch mechanism protrudes from the cradle portion 102 when the cradle is not attached to the tablet portion 104.

FIG. 3 illustrates an embodiment of the detachable convertible device in a detached state from an alternate viewing angle. Again, in this state, the device from FIG. 1 now is shown with the tablet portion 104 detached from the cradle portion 102. A slot 300 to receive the hook portion 200 of the latch mechanism is shown in FIG. 3. In other embodiments that are not shown in FIG. 2 or 3, the latch mechanism may be housed in the tablet casing and the slot may be housed in the cradle casing.

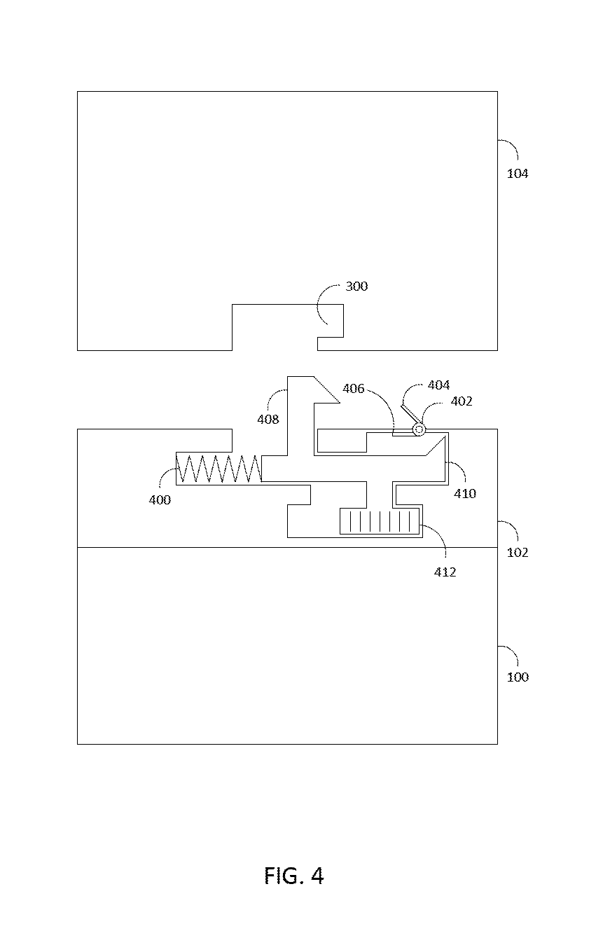

FIG. 4 illustrates an embodiment of a mechanical stop that keeps the latch open when actuated and that resets once the user pulls the tablet away from the base. More specifically, FIG. 4 illustrates an embodiment of a mechanical stop latch mechanism in an unattached state. In the unattached state, the base portion 100 and cradle portion 102 of the detachable convertible device are unattached (i.e., detached) from the tablet portion 104. This figure shows a cross section of the device, thus some relevant elements internal to the housings of the cradle portion 102 and tablet portion 104 are shown.

As described above and shown in FIG. 4, the latch mechanism, which also may be referred to as a hook latch assembly, is shown as being housed in the cradle portion 102 of the device. The hook latch assembly may include a first spring 400, shown here has a coil compression spring, a second spring 402, shown with two extruding portions (404 and 406) from the spring, a first hook tab 408 that extrudes from the cradle 102, a second hook tab 410 internal to the cradle 102, and a slider mechanism 412 that a user can slide between at least two positions with, for example, a finger. If this were not a cross sectional figure, likely the only elements of the hook latch assembly visible to a user would be the first tab 408, the slider mechanism, and a portion of the second spring 402. In many embodiments, the second spring 402 is in a rest position when the two extruding portions 404 and 406 are extruding at angles apart from each other. This rest angle between the two extruding portions generally would be more than 0 degrees and less than 90 degrees, with about 45 degrees being a standard angle.

In this position, the hook latch assembly is at rest because the first spring 400 is in a resting position, referred to as the closed (e.g., latched) position. The first spring, when compressed will exert force to return the hook latch assembly to the closed position. Without any other intervening circumstances, the first spring would cause the mechanism to return to this position. Although, the slider mechanism 412, under the force of a user's finger, can be used to override this first spring force and move the entire assembly to an open position.

Additionally, in this position, the second spring 402 rest position, shown in FIG. 4, also is at rest when the extruding portion 404 extrudes from the cradle portion 102 of the device.

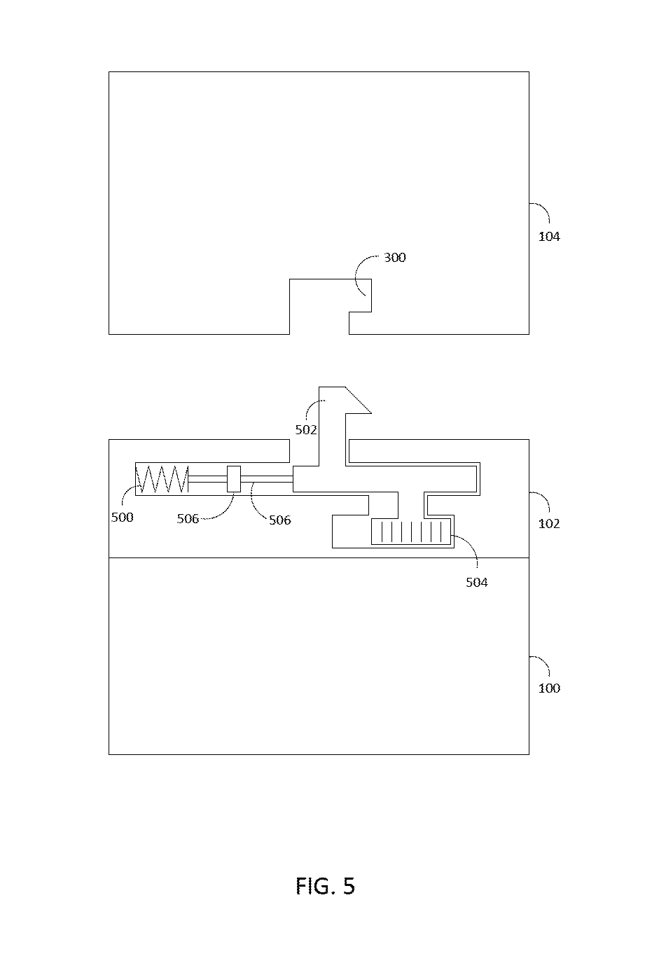

FIG. 5 illustrates another embodiment of a mechanical stop that keeps the latch open when actuated and that resets once the user pulls the tablet away from the base.

In FIG. 5, the hook latch assembly includes a spring 500, a hook tab 502, and a slider mechanism 504, which function similarly to those same elements in FIG. 4 through FIG. 6. Additionally, in FIG. 5, a rod 506 that couples the spring 500 to the rest of the hook latch assembly is shown. Located on the rod 506 is a damper mechanism 508. FIG. 5 shows the hook latch assembly in its rest state, which can be manipulated into a non-rest state by a user applying force to the slider mechanism 504 to compress spring 500 and move the entire hook latch assembly into an open state. Once the hook latch assembly gets to the open state, the damper mechanism is capable of keeping the hook latch assembly in the open state for a few seconds. After this amount of time, which may be determined by the manufacturer of the damper or during installation of the damper into the cradle housing, the damper essentially times out and causes the hook latch assembly to return to the latched position under the force of the spring 500. In different embodiments, this desired delay return effect can be achieved by the spring and damper elements being in a parallel configuration or having a viscoelastic type of material to be used for the damper and/or spring, such as memory foam.

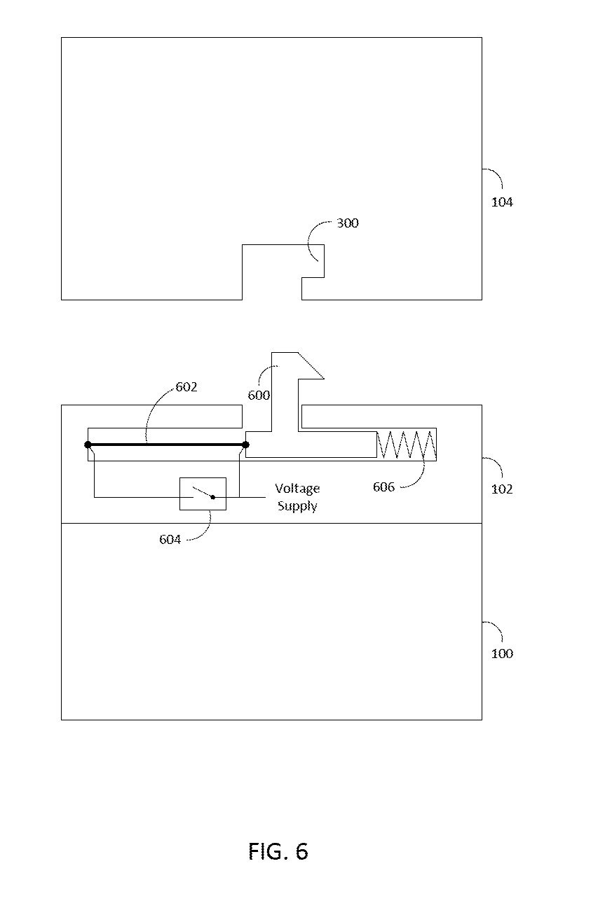

FIG. 6 illustrates an embodiment of an electrical latch actuator to provide a time delay, which again will allow the user enough time to retrieve the detachable tablet. In FIG. 8, the hook latch assembly includes a hook tab 600, which functions similarly to that same element in FIG. 4 through FIG. 5. Additionally, in FIG. 6, a shape memory wire 602 is present as a portion of the hook latch assembly. The shape memory wire 602 will contract when a current/voltage is applied to the wire, when contracted, the latch will move to the open position. The current/voltage is applied through a switch 604, that connects the shape memory wire 602 to a voltage supply. The switch 604 may include a button on the external housing of the cradle portion 102 to allow the user to physically push the button to apply the current/voltage and cause the shape memory wire 602 to contract. The shape memory wire 602 works by contracting at the elevated temperature induced by the current. It's not until the wire cools down that the wire expands again. There is a time constant associated with this event which if designed correctly would allow the user enough time to retrieve the tablet.

In many embodiments, a return spring 606 may additionally be utilized to pull the hook latch assembly back to the at rest closed position once the memory shape wire cools.

Although not shown in FIG. 4 through FIG. 6, in many embodiments, the hook latch assembly includes multiple extruding tabs along the attach plane to more securely latch the tablet portion of the device to the cradle portion.

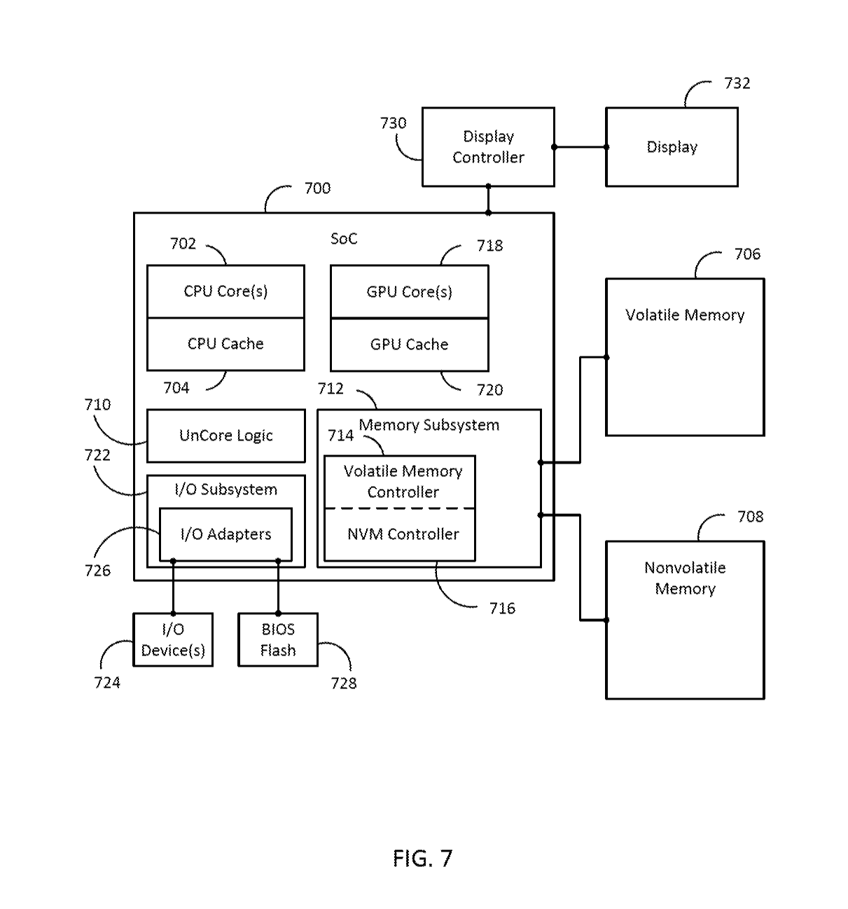

FIG. 7 illustrates system hardware logic that may be present in the detachable convertible device. This hardware logic could be in the tablet portion, cradle portion, base portion or any combination of those three portions of the device. As shown in the embodiment of the system illustrated in FIG. 7, the system logic is implemented in a system on a chip (SoC) package 700 that may include many portions of the functional logic within the detachable convertible device. Other embodiments that include several discrete logic devices may also be implemented in the detachable convertible device, but are not shown. The SoC has a central processing unit (CPU), which includes one or more cores 702. Although not shown, each core may internally include one or more instruction/data caches, execution units, prefetch buffers, instruction queues, branch address calculation units, instruction decoders, floating point units, retirement units, etc.

The SoC 700 also includes at least one lower level cache, such as CPU cache 704. This may be a general purpose cache that is capable of storing a significant amount of data retrieved from memory locations in volatile memory 706 and/or nonvolatile memory 708. In different embodiments, CPU cache 704 may be shared among all cores or each core may have its own lower level cache.

SoC 700 may also include UnCore Logic 710 that incorporates components coordinating and operating core(s) 702. UnCore Logic 710 may include, for example, a power control unit (PCU). The PCU may include logic and components needed for regulating the power state of the core(s) among other tasks.

In FIG. 7, the SoC 700 also includes a memory subsystem 712. The memory subsystem 712 may include a volatile memory controller 714, which may be utilized to provide access to volatile memory 706. the memory subsystem 712 may also include a nonvolatile memory controller 716 to provide access to the nonvolatile memory 708. Other storage devices, such as solid state drives, hard drives, etc. could also be present, though these are not shown. The memory subsystem stores instructions and data to be operated upon by the CPU and graphics cores. In some embodiments, these instructions and data that help operate the detachable convertible device may be all or partially stored in volatile memory during active operations and stored in nonvolatile memory storage when the detachable convertible device is not in an operational state (e.g., in a low power mode or turned off).

Additionally, SoC 700 includes a graphics subsystem that includes one or more graphics processing unit (GPU) cores 718 and one or more GPU caches 720.

In many embodiments, an input/output (I/O) subsystem is present in the system in FIG. 7 to communicate with I/O devices, such as I/O device(s) 724. The I/O subsystem 722 in FIG. 7 is integrated into the SoC 700, though in other embodiments that are not shown, the I/O subsystem may be on a chip discrete from the CPU(s). Within the I/O subsystem 722, one or more I/O adapter(s) 726 are present to translate a host communication protocol utilized within the CPU 104 to a protocol compatible with particular I/O devices. Some of the protocols that adapters may be utilized for translation include Peripheral Component Interconnect (PCI)-Express (PCI-E), 3.0; Universal Serial Bus (USB), 3.0; Serial Advanced Technology Attachment (SATA), 3.0; Small Computer System Interface (SCSI), Ultra-640; and Institute of Electrical and Electronics Engineers (IEEE) 1394 “Firewire;” among others.

Additionally, there may be one or more wireless protocol I/O adapters. Examples of wireless protocols, among others, are used in personal area networks Bluetooth, wireless USB, wireless local area networks, such as IEEE 802.11-based wireless protocols, and cellular protocols (such as 3G, 4G, LTE, etc.).

A Basic Input/Output System (BIOS) flash 728 device may additionally be present in the system to provide a set of boot instructions when the system powers on or reboots. For BIOS flash 728 device, some of the protocols that I/O adapters 726 may translate include Serial Peripheral Interface (SPI), Microwire, among others.

A display controller 730 receives visual information from the graphics subsystem and provides it to the display 732 (e.g., the touch-sensitive display discussed above) to be visually displayed.

In the description above and in the claims, the terms “include” and “comprise,” along with their derivatives, may be used, and are intended to be treated as synonyms for each other. In addition, in the following description and claims, the terms “coupled” and “connected,” along with their derivatives may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate, interact, or communicate with each other.

In the description above, certain terminology is used to describe embodiments. For example, the term “logic” is representative of hardware, firmware, software (or any combination thereof) to perform one or more functions. For instance, examples of “hardware” include, but are not limited to, an integrated circuit, a finite state machine, or even combinatorial logic. The integrated circuit may take the form of a processor such as a microprocessor, an application specific integrated circuit, a digital signal processor, a micro-controller, or the like.

It should be appreciated that reference throughout this specification to “one embodiment” or “an embodiment” means that a particular feature, structure or characteristic described in connection with the embodiment is included in at least one embodiment. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments.

Similarly, it should be appreciated that in the foregoing description of disclosed embodiments, various features are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claimed subject matter requires more features than are expressly recited in each claim. Rather, as the following claims reflect, inventive aspects lie in less than all features of a single foregoing disclosed embodiment. Thus, the claims following the detailed description are hereby expressly incorporated into this detailed description.

1. A device, comprising:
a latch to have at least a rest position and a non-rest position, wherein the latch to receive a manipulation force to move the latch from the rest position to the non-rest position, and wherein the latch to delay returning to the rest position after a period of time.

2. The device of claim 1, wherein the latch to be integrated into a computing device and to attach a first portion of the computing device to a second portion of the computing device.

3. The device of claim 1, further comprising:
a first spring to cause the latch to default to the rest position.

4. The device of claim 2, further comprising:
an external slider coupled to the latch, the external slider to receive the manipulation force.

5. The device of claim 4, further comprising:
a second spring including at least a first portion and a second portion, the first portion of the second spring to protrude from an edge of the first portion of the computing device while in the rest position and while the first and second portions of the computing device are unattached.

6. The device of claim 5, wherein the second spring to rotate into a non rest position in response to the first and second portions of the computing device being attached, wherein, when the latch is an open position., the second portion of the second spring to stop the latch from returning to the rest position while the first and second portions of the computing device are attached.

7. The device of claim 4, further comprising:
a damper element to cause a delay to the first spring to return to the closed position.

8. The device of claim 4, further comprising:
a shape memory wire to contract when a current is applied and to expand when the current is not applied, wherein contraction of the shape memory wire to cause the hook latch assembly to move to the open position.

9. A method, comprising:
receiving a manipulation force at a hook latch assembly, the hook latch assembly to at least have a rest position and a non-rest position;
in response to receiving the manipulation force, moving the hook latch assembly from the rest position to the non-rest position; and
delaying the hook latch assembly from returning to the rest position for a period of time.

10. The method of claim 9, further comprising:
attaching a first portion of a computing device to a second portion of the computing device with the hook latch assembly.

11. A device, comprising:
a first casing to house a hook latch assembly, the hook latch assembly to include at least one hook tab to attach the first casing to a second casing; and
wherein the hook latch assembly,
when in a closed position with at least a portion of the first casing and a portion of the second casing proximate to each other at an attach plane, to cause the first casing to attach to the second casing, the hook latch assembly to default to the closed position;
when manipulated to an open position, to cause the first casing to be allowed to release from the second casing; and
to implement a time delay from a first time when the hook latch assembly is manipulated into the open position to a second time when the hook latch assembly has returned to the closed position.

12. The device of claim 11, wherein the second casing further comprises at least one slot to receive the at least one hook tab.

13. The device of claim 11, wherein the second casing further comprises a display.

14. The device of claim 11, wherein the hook latch assembly comprises a first spring, the first spring to cause the hook latch assembly to default to the closed position.

15. The device of claim 11, wherein the hook latch assembly comprises an external slider to allow manipulation of the hook latch assembly position.

16. The device of claim 15, further comprising:
a second spring coupled to a portion of the first casing at a position proximate to the attach plane, the second spring including at least a first portion and a second portion, the first portion of the second spring to protrude from the first casing while in a rest position, wherein the second spring to be in the rest position in response to the first casing being unattached from the second casing.

17. The device of claim 16, wherein the second spring to rotate into a non rest position in response to at least the portion of the first casing and the portion of the second casing proximate to each other at the attach plane, the second portion of the second spring to prevent the hook latch assembly from returning to the closed position when the external slider manipulates the hook latch assembly to the open position, until at least the portion of the first casing and the portion of the second casing no longer are proximate to each other at the attach plane.

18. The device of claim 15, wherein the hook latch assembly further comprises a damper element to cause a delay to the first spring to return to the dosed position, the delay to create an amount of time between the first time and the second time.

19. The device of claim 15, wherein the hook latch assembly further comprises a shape memory wire to contract when a current is applied and to expand when the current is not applied, wherein contraction of the shape memory wire to cause the hook latch assembly to move to the open position.

20. A system, comprising:
a second casing comprising at least one slot to receive at least one hook tab; and
a first casing to house a hook latch assembly, the hook latch assembly to include the at least one hook tab to attach the first casing to the second casing;
wherein the hook latch assembly,
when in a closed position with at least a portion of the first casing and a portion of the second casing proximate to each other at an attach plane, to cause the first casing to attach to the second casing, the hook latch assembly to default to the closed position;
when manipulated to an open position, to cause the first casing to be allowed to release from the second casing; and
to implement a time delay from a first time when the hook latch assembly is manipulated into the open position to a second time when the hook latch assembly has returned to the closed position.

21. The system of claim 20, wherein the second casing further comprises a display.

22. The system of claim 20, wherein the hook latch assembly comprises a first spring, the first spring to cause the hook latch assembly to default to the closed position.

23. The system of claim 20, wherein the hook latch assembly comprises an external slider to allow manipulation of the hook latch assembly position.

24. The system of claim 23, further comprising:
a second spring coupled to a portion of the first casing at a position proximate to the attach plane, the second spring including at least a first portion and a second portion, the first portion of the second spring to protrude from the first casing while in a rest position, wherein the second spring to be in the rest position in response to the first casing being unattached from the second casing.

25. The system of claim 24, wherein the second spring to rotate into a non rest position in response to at least the portion of the first casing and the portion of the second casing proximate to each other at the attach plane, the second portion of the second spring to prevent the hook latch assembly from returning to the closed position when the external slider manipulates the hook latch assembly to the open position, until at least the portion of the first casing and the portion of the second casing no longer are proximate to each other at the attach plane.

26. The system of claim 23, wherein the hook latch assembly further comprises a damper element to cause a delay to the first spring to return to the closed position, the delay to create an amount of time between the first time and the second time.

27. The system of claim 23, wherein the hook latch assembly further comprises a shape memory wire to contract when a current is applied and to expand when the current is not applied, wherein contraction of the shape memory wire to cause the hook latch assembly to move to the open position and.
